(19) United States
(12) Patent Application Publication
(10) Pub. No.: US 2005/0056946 A1
(43) Pub. Date: Mar. 17, 2005

(54) Electrical circuit assembly with improved shock resistance

(75) Inventor: Kenneth B. Gilleo, Cranston, RI (US)

Correspondence Address: SENNIGER POWERS LEAVITT AND ROEDEL, ONE METROPOLITAN SQUARE, 16TH FLOOR, ST LOUIS, MO, 63102, US

(73) Assignee: Cookson Electronics, Inc.

(21) Appl. No.: 10/663,253

(22) Filed: Sep. 16, 2003

(51) Int. Cl. H01L 29/40; H01L 21/48

(52) U.S. Cl. 257/783; 257/782; 257/778; 257/780; 438/118; 438/108; 438/614

(57) ABSTRACT

An assembly of the present invention includes a substrate and an integrated circuit device adapted to be electrically and mechanically attached to the substrate. Electrically conductive connecting elements between the device and the substrate electrically connect the device and the substrate. At least one adhesive body is positioned between the integrated circuit device and the substrate to form a mechanical connection between the circuit device and the substrate. The at least one adhesive body comprises a non-thermosetting material which, when heated, releases said mechanical connection to allow removal of the circuit device from the substrate.

### BACKGROUND OF THE INVENTION

The present invention relates generally to an electrical circuit assembly, and more particularly to a mechanical connection between a microchip and a substrate.

Small portable electronic devices such as cellular phones contain various integrated circuit devices (i.e., microchips, chips, or dies) that are electrically and mechanically connected to a substrate (e.g., printed circuit board) to form an integrated circuit that controls the operation of the device. Portable electronic devices must withstand operation in rugged environments and sustain impact forces resulting from frequent dropping of the devices without failure of the integrated circuit. Prior to shipment of the finished electronic device, electronic manufacturers typically perform a drop test on the final assembly of the device to test the attachment force of the integrated circuit components to the circuit board. To pass the drop test, the finished product must withstand being dropped from a specified height (e.g., about 6 feet) onto a hard surface without failure of its integrated circuit components.

Integrated circuit devices are typically connected to a substrate using well-know methods such as Direct Chip Attach (DCA) commonly referred to as “flip chip”. Reference may be made to U.S. Pat. No. 5,439,162, incorporated by reference herein for all purposes, for additional background information regarding DCA. DCA uses joining materials such as metallurgical solders or polymeric conductive adhesives that are typically applied to the electrical connection pads (i.e, bond pads) of the chip. The chip can then be electrically connected to corresponding bond pads on a substrate by applying heat to melt, or reflow the solder. A protective thermoset polymer, called underfill, is applied to the gap between the chip and substrate and then hardened by heating to lock together the chip and substrate so that differences in thermal expansion do not break or damage the electrical connection. The use of underfill results in a permanent bond between the chip and the substrate that must be mechanically broken to remove the chip from the substrate. Underfill is used to improve thermocycling between the chip and the circuit board as well as to enhance the mechanical connection force between the chip and the circuit board so that the electronic device will pass the drop test. Since underfill is a thermoset polymer that cannot be softened by heating, rework of the connection holding the circuit device to the substrate is time consuming and costly.

Chip Scale Packages and other chip packages have been developed that enclose the microchip to protect the chip from being damaged. Also, another advantage of chip packages is that they protect the chip from thermal stresses resulting from the different rates of thermal expansion of the chip and the circuit board. Chip packages eliminate the requirement for a thermosetting underfill to reduce thermal stresses between the package and the circuit board because the package is designed to protect the microchip from the thermal stresses that occur during operation. However, in order to pass the drop test, underfill is typically applied to mechanically attach a chip package to a circuit board. By using underfill to attach a chip package to a circuit board, the full benefits of using a chip package rather than a microchip directly attached to the circuit board are not realized because chip attachments using underfill are considered permanent connections that cannot readily be released. Therefore, a need exists for an alternative to using underfill that allows a releasable mechanical connection between the circuit device and a substrate.

### SUMMARY OF THE INVENTION

Among the several objects of this invention may be noted the provision of an assembly which includes a releasable mechanical connection between an integrated circuit device and a substrate; the provision of such an assembly which allows economical manufacture; the provisions of such an assembly which permits simple testing; the provision of such an assembly which reduces assembly time; the provisions of such an assembly which provides a reliable electrical and mechanical connection; and the provision of such an assembly that allows easy removal and replacement of the integrated circuit device.

In general, an assembly of the present invention comprises a substrate and an integrated circuit device adapted to be electrically and mechanically attached to the substrate. Electrically conductive connecting elements between the device and the substrate electrically connect the device and the substrate. At least one adhesive body is positioned between the integrated circuit device and the substrate to form a mechanical connection between the circuit device and the substrate. The at least one adhesive body comprises a non-thermosetting material which, when heated, releases said mechanical connection to allow removal of the circuit device from the substrate.

In another aspect of the invention the assembly comprises a substrate and an integrated circuit device adapted to be electrically and mechanically attached to the substrate. Electrically conductive connecting elements between the device and the substrate electrically connect the device and the substrate. At least two adhesive bodies comprising a non-thermosetting material are positioned between the integrated circuit device and the substrate to form a releasable mechanical connection between the circuit device and the substrate.

Another aspect of the invention is directed to a process for attaching an integrated circuit device to a substrate. The process comprises the steps of aligning an integrated circuit device on the substrate and electrically connecting the circuit device and the substrate. At least one adhesive body is positioned between the device and the substrate. Heat is applied to the at least one adhesive body so that the body is bonded to the device and the substrate to form a releasable connection therebetween.

Other objects and features will be in part apparent and in part pointed out hereinafter.

### BRIEF DESCRIPTION OF THE DRAWINGS

FIG. 1 is an elevation, partially in section, of one embodiment of an electrical circuit assembly of the present invention;

FIG. 2 is a top plan view of a circuit device of the assembly of FIG. 1 showing a first possible arrangement of adhesive bodies relative to the circuit device;

FIG. 3 is a view similar to FIG. 2 showing a second possible arrangement of adhesive bodies relative to the circuit device;

FIG. 4 is a schematic showing a first process for assembling an electrical circuit assembly of the present invention; and

FIG. 5 is a schematic showing a second process for assembling an electrical circuit assembly of the present invention.

Corresponding parts are designated by corresponding reference numbers throughout the drawings.

### DETAILED DESCRIPTION OF PREFERRED EMBODIMENTS

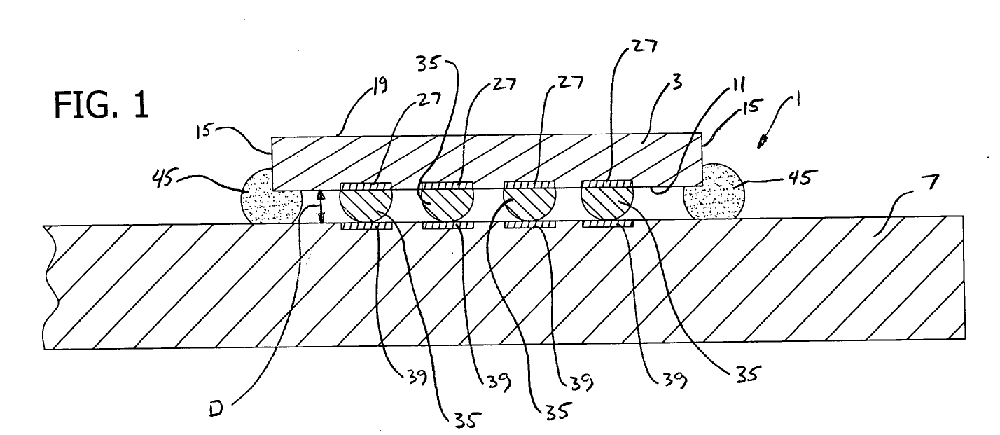

Referring now to the drawings, and more particularly to FIG. 1, an electrical circuit assembly, generally designated 1, comprises an integrated circuit (IC) device 3 assembled in accordance with the present invention. In the particular embodiment of FIG. 1, the IC device 3 is electrically and mechanically attached to a substrate 7 in the form of a printed circuit board of an electronic device (not shown). It will be understood that the circuit device 3 could be attached to a chip carrier substrate or other conventional connecting substrates (e.g., a pin-grid array or a land grid array) without departing from the scope of this invention. Also, the assembly 1 could include more than one IC device 3 assembled in accordance with the present invention.

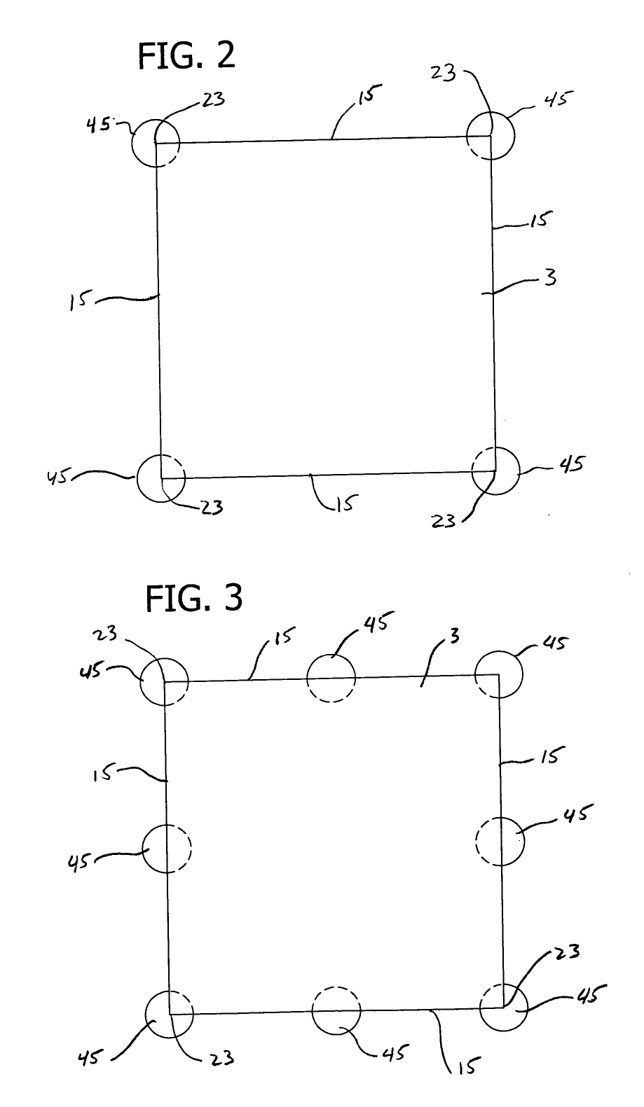

In the illustrated embodiments, the IC device 3 is shown schematically but it will be understood that each device could comprise any typical IC device such as a Micro-Electronic Mechanical Systems (MEMS) device, Optoelectronic (OE) device or any other microchip that may be used in an electrical circuit assembly. Also, the IC device 3 could be a preassembled chip scale package (CSP), Multi-Chip Module (MCM) or any other circuit device package that may be used in an electrical circuit assembly. As shown in FIGS. 1 and 2, the IC device 3 is rectangular with a substantially flat bottom surface 11 that opposes the substrate 7, four generally flat side surfaces 15 (only two of which are shown in FIG. 1) that are substantially perpendicular to the flat bottom surface, and a top surface 19 substantially parallel with the flat bottom surface. The IC device 3 has four corners 23 (FIG. 2) at the intersection of the side surfaces 15. As shown in FIG. 1, the IC device 3 has electrical connection pads 27 on the flat bottom surface 11 that are arranged for electrical connection with the substrate 7 so that electrical signals can be passed from the substrate to the IC device.

As shown in FIG. 1, the assembly 1 has electrically conducting connection elements 35 in the form of solder spheres that electrically connect the IC device 3 to the substrate 7. It will be understood that the solder spheres 35 are placed at locations corresponding to the electrical connection pads 27 on the IC device 3 and electrical connection pads 39 on the circuit board 7 so that electrical signals can pass between the IC device and the circuit board. After the IC device 3 is placed on the solder spheres 35, the board 7 is passed through a reflow oven (not shown) to heat the board and reflow the solder to electrically connect the IC device to the board. In the illustrated embodiment, the solder spheres 35 are located toward the center of the IC device 3 but it will be understood that the solder spheres could be located at a peripheral edge of the device or at other locations without departing from the scope of this invention. It is noted that the mechanical holding force provided by the solder spheres 35 alone is not sufficient to withstand impact forces that are applied to the electrical circuit assembly 1 either during normal use of the electronic device or during a drop test performed prior to shipment of the electronic device.

As shown in FIGS. 1 and 2, the IC device 3 has adhesive bodies 45 located at the corners 23 of the device to mechanically connect the IC device to the substrate 7. The adhesive bodies 45 are positioned between the IC device 3 and the substrate 7 in contact with the flat bottom surface 11 and side surfaces 15 of the IC device. The adhesive bodies 45 are located on the periphery of the IC device 3 after the solder spheres 35 have been positioned to electrically connect the IC device to the substrate 7. In the illustrated embodiment, the adhesive bodies 45 are discrete spheres of adhesive material but it will be understood that the bodies could have other shapes and sizes. As shown in FIG. 2, the adhesive bodies 45 may be positioned at the corners 23 of the IC device 3 to mechanically connect the circuit device to the substrate 7. As shown in FIG. 3, the adhesive bodies 45 could also be placed between the IC device 3 and the substrate 7 at locations along the edges of the device between adjacent corners 23 of the device. Although, the adhesive bodies 45 are shown in FIG. 3 as being approximately equidistant from adjacent corners 23 of the IC device 3, it will be understood that the adhesive bodies 45 could be otherwise positioned on or near the peripheral edge of the circuit device and that additional adhesive bodies could be placed between the IC device and the substrate.

In the illustrated embodiments, the adhesive bodies 45 are located adjacent the peripheral edge of the flat bottom surface 11 of the IC device 3 so that the bodies contact both the bottom surface and the flat side surface(s) 15 of the IC device. Positioning the adhesive bodies 45 in contact with both the flat bottom surface 11 and at least one side surface 15 enhances the mechanical holding force of the bodies. Alternatively, the adhesive bodies 45 could be spaced in from the side surfaces 15 of the IC device 3 so that the bodies only contact the flat bottom surface 11 of the device. Further, the adhesive bodies 45 could be located at any location on the bottom surface 11 of the IC device without departing from the scope of this invention.

The adhesive bodies 45 of the present invention comprise a non-thermosetting polymer material that allows a releasable connection between the IC device 3 and the substrate 7. In one particular embodiment, each adhesive body 45 comprises a thermoplastic polymer that has been formed into discrete spheres of material. The thermoplastic material of the adhesive body 45 is desirably a high molecular weight polymer that has the unique capability of softening or re-melting when heated and returning to a solid when cooled. Upon placement between the circuit device 3 and the substrate 7, each adhesive body is heated to soften or melt and adhere to the IC device and substrate. Upon cooling, the adhesive body 45 solidifies to form a joint that mechanically attaches the IC device 3 to the substrate 7. The adhesive body 45 can be reheated to soften or melt the body to release the mechanical connection and allow the IC device 3 to be readily removed, repaired and replaced using the same adhesive bodies or new bodies. In this way, the adhesive bodies 45 of the present invention provide a releasable connection between the IC device 3 and the substrate 7. The releasable connection allows defective IC devices 3 discovered during final testing of the completed electrical circuit assemblies 1 to be easily replaced on the substrate 7 (e.g., circuit board) without damage to the substrate or other components.

In one embodiment, the adhesive bodies 45 comprise a thermoplastic polymer commonly sold under the trade name STAYSTIK® by Cookson Electronics of Alpharetta, Ga. Reference may be made to U.S. Pat. Nos. 5,061,549 and 5,401,536, both of which are incorporated by reference herein for all purposes, for additional information regarding STAYSTIK® thermoplastic adhesives. The adhesive bodies 45 could comprise other thermoplastics (e.g., polysulfones) that may include a small amount (e.g., about 1% to 5% by weight) of carbon black to absorb infrared and near-infrared radiation and improve strength. The adhesive bodies 45 can comprise any thermoplastic capable of melting and bonding to the IC device 3 and the substrate 7. Wetting agents and strength boosters can be added to reduce the coefficient of thermal expansion of the bodies 45 to match that of the solder spheres 35, thus reducing thermal stress on the connection between the IC device 3 and the substrate 7. The adhesive bodies 45 could comprise a core material that is coated with an outer adhesive layer or adhesion primer. The bodies 45 could comprise a B-stage adhesive (e.g., epoxy) that melts before polymerizing so as to bond to the IC device 3 and substrate 7. If a B-stage adhesive is used, the adhesive bodies 45 would have increased bond strength but the mechanical connection between the IC device 3 and the substrate 7 would be more difficult to release.

Regardless of the specific material used, the softening point of the adhesive bodies 45 should be higher than the operating temperature of the assembly 1 and can be above the solder reflow temperature if desired. For example, each adhesive body 45 may have a bonding temperature ranging from about 100 degrees Celsius to about 375 degrees Celsius and the solder spheres 35 may have a reflow temperature ranging from about 180 degrees Celsius to about 300 degrees Celsius. The bonding time (i.e., the time required to hold the temperature of the adhesive bodies 45 at the bonding temperature) of each adhesive body may be approximately 10 seconds or lower depending on the specific material properties of the thermoplastic used.

The adhesive bodies 45 have a minimum diameter equal to at least approximately the distance D (FIG. 1) between the IC device 3 and the substrate 7. The minimum diameter of the adhesive bodies 45 and the distance D can range from approximately 8 to 900 microns. More preferably, the diameter of the adhesive bodies 45 is approximately 1.5 times the distance D between the IC device 3 and the substrate 7 so that the bodies contact the side surfaces 15 when placed at the peripheral edge of the IC device. It will be understood that the adhesive bodies 45 can have other dimensions and can be otherwise arranged without departing from the scope of this invention

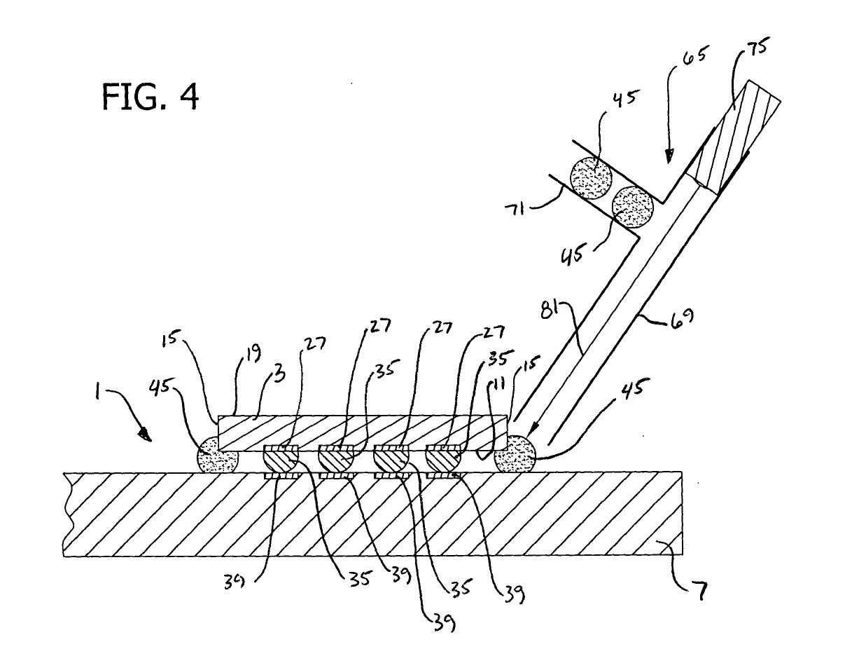

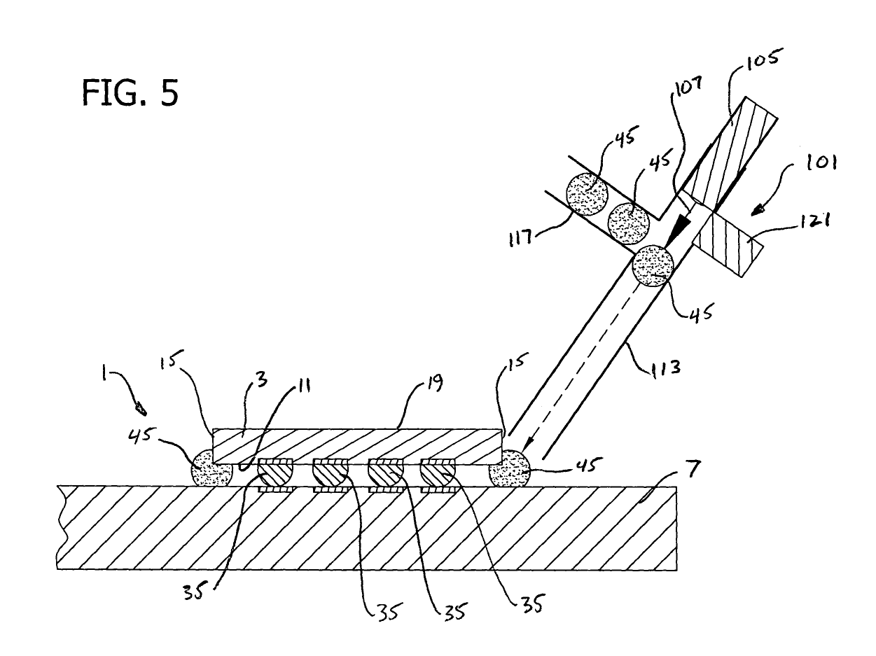

Referring to FIGS. 4 and 5, the electrical circuit assembly 1 of the present invention can be formed by an assembly process that attaches the IC device 3 to the substrate 7. The process comprises placing the solder spheres 35 on the electrical connection pads 39 of the substrate 7 and aligning the IC device 3 so that the electrical connection pads 27 of the device are aligned for contact with the solder spheres. The IC device 3 is electrically connected to the substrate 7 by heating the solder spheres 35 to reflow the solder and complete the electrical connection between the IC device and the substrate. As shown in FIG. 4, a number of adhesive bodies 45 may be positioned between the IC device 3 and the substrate 7 by a gravity feed mechanism, generally indicated 65, at locations around the periphery of the IC device. The adhesive bodies 45 may be located around the periphery of the IC device 3 as shown in FIGS. 2 and 3, or the adhesive bodies may be otherwise located. The gravity feed mechanism 65 has a guide tube 69 for positioning the adhesive bodies 45 between the IC device 3 and the substrate 7, a magazine 71 for feeding adhesive bodies to the tube, and a laser 75 to provide a localized radiant energy beam 81 to heat the adhesive body after placement between the IC device and the substrate.

As shown in FIG. 5, the adhesive bodies 45 may be placed by a jetting mechanism, generally indicated 101, that is equipped with a laser 105 for generating a localized radiant energy beam 107 to heat the bodies. The jetting mechanism 101 comprises a guide tube 113, a magazine 117 having a supply of adhesive bodies 45, and a pneumatic ejector 121 which provides a burst of air or other gas to eject an adhesive body through the guide tube to a desired location between the IC device 3 and the substrate 7.

With either the gravity feed mechanism 65 or the jetting mechanism 101, the adhesive bodies 45 may be preheated before placement between the IC device 3 and the substrate 7 or the bodies may be heated as they exit the mechanism so that assembly time is reduced. Preferably, the gravity feed mechanism 65 and jetting mechanism 101 are components of a programmable machine (not shown) that may be used to automatically and precisely place each adhesive body 45 and apply the exact amount of heat to the body for the required bonding time of the specific adhesive body used. The jetting mechanism 101 may be similar to the jet soldering system disclosed in U.S. Pat. No. 6,276,589, incorporated by reference herein for all purposes, in that the adhesive bodies 45 may be molten plastic that is directed to the bond site between the IC device 3 and substrate 7. The gravity feed mechanism 65 or jetting mechanism 101 may be designed to extract the adhesive bodies 45 from the electrical circuit assembly 1 by applying heat to release the mechanical connection between the IC device 3 and the substrate 7 and using vacuum pressure to extract each adhesive body.

In view of the above, it will be seen that the several objects of the invention are achieved and other advantageous results attained. The adhesive bodies 45 of the electrical circuit assembly 1 establish a releasable mechanical connection between the IC device 3 and the substrate 7 that provides sufficient mechanical holding force for reliable operation of the circuit assembly. The adhesive bodies 45 comprise a non-thermosetting material that allows the mechanical connection to be formed by the quick application of localized heating to the adhesive bodies. The connection can be released by reheating the adhesive bodies 45 allowing the IC device 3 to be easily removed, repaired and/or replaced.

As various changes could be made in the above constructions without departing from the scope of the invention, it is intended that all matter and dimensions contained in the above description or shown in the accompanying drawings shall be interpreted as illustrative and not in a limiting sense. For example, the adhesive bodies 45 could have alternative shapes and sizes and could otherwise be located between the IC device 3 and the substrate 7 to provide a mechanical attachment force holding the device to the substrate. The adhesive bodies 45 may be positioned and heated by either the gravity feed mechanism 65, the jetting mechanism 101, or any other mechanism capable of positioning the bodies and applying heat. The gravity feed mechanism 65 and/or jetting mechanism 101 can move relative to the substrate 7 or the substrate 7 can move relative to the mechanism to accurately position the adhesive bodies 45. The gravity feed mechanism 65, jetting mechanism 101, and/or the substrate 7 can be tilted at an angle to properly position the adhesive bodies 45. Also, the gravity feed mechanism 65 or jetting mechanism 101 may comprise multiple guide tubes 69, 109 to allow simultaneous placement of multiple adhesive bodies 45. Alternatively, the adhesive bodies 45 may be positioned and heated in separate steps by using separate devices. Also, the bodies 45 may be heated by induction, convection, or conduction heating or any other heating method.

When introducing elements of the present invention or the preferred embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

1. An assembly comprising
a substrate,
an integrated circuit device adapted to be electrically and mechanically attached to the substrate,
electrically conductive connecting elements between the device and the substrate that electrically connect the device and the substrate, and
at least one adhesive body positioned between the integrated circuit device and the substrate to form a mechanical connection between the circuit device and the substrate,
said at least one adhesive body comprising a non-thermosetting material which, when heated, releases said mechanical connection to allow removal of the circuit device from the substrate.

2. The assembly as set forth in claim 1 wherein said non-thermosetting material comprises a thermoplastic polymer.

3. The assembly as set forth in claim 2 wherein said thermoplastic polymer has a bonding temperature of at least about 100 degrees Celsius.

4. The assembly as set forth in claim 2 wherein said thermoplastic polymer has a bonding temperature of less than about 300 degrees Celsius.

5. The assembly as set forth in claim 1 wherein said at least one adhesive body is positioned at a peripheral edge of the integrated circuit device.

6. The assembly as set forth in claim 5 wherein said circuit device has corners and the adhesive bodies are located at said corners.

7. The assembly as set forth in claim 1 wherein said at least one adhesive body has a substantially spherical shape.

8. The assembly as set forth in claim 1 wherein said at least one adhesive body comprises four adhesive bodies.

9. The assembly as set forth in claim 1 wherein said integrated circuit device is a chip package.

10. The assembly as set forth in claim 1 wherein said integrated circuit device is a multi-chip module.

11. The assembly as set forth in claim 1 wherein said integrated circuit device has a bottom surface with four corners and said at least one adhesive body is located approximately equidistant from adjacent corners in contact with the bottom surface of the circuit device.

12. An assembly comprising
a substrate,
an integrated circuit device adapted to be electrically and mechanically attached to the substrate,
electrically conductive connecting elements between the device and the substrate that electrically connect the device and the substrate, and
at least two adhesive bodies comprising a non-thermosetting material positioned between the integrated circuit device and the substrate to form a releasable mechanical connection between the circuit device and the substrate.

13. The assembly as set forth in claim 12 wherein said releasable mechanical connection is released by heating said adhesive bodies.

14. The assembly as set forth in claim 12 wherein said at least two adhesive bodies are spaced apart to form an open space between the adhesive bodies.

15. The assembly as set forth in claim 12 wherein said at least two adhesive bodies are positioned at a periphery of the integrated circuit device.

16. The assembly as set forth in claim 12 wherein said integrated circuit device has corners and the at least two adhesive bodies comprise four adhesive bodies positioned at said corners.

17. The assembly as set forth in claim 12 wherein said at least two adhesive bodies comprise a thermoplastic polymer.

18-24. (Cancelled)
